(19) United States
(12) Patent Application Publication
(10) Pub. No.: US 2026/0293306 A1
(43) Pub. Date: Sep. 24, 2026

(54) STAGGERED STACKED FIELD EFFECT TRANSISTOR CONTACT TO EPI WITH INCREASED CONTACT AREA

(71) Applicant: INTERNATIONAL BUSINESS MACHINES CORPORATION, ARMONK, NY (US)

(72) Inventors: Debarghya Sarkar, Latham, NY (US); Ruilong Xie, Niskayuna, NY (US); Oleg Gluschenkov, Tannersville, NY (US); Junli Wang, Slingerlands, NY (US)

(21) Appl. No.: 19/086,563

(22) Filed: Mar. 21, 2025

(51) Int. Cl. H10D 84/85; H01L 23/00; H01L 25/065; H10D 30/00; H10D 30/01; H10D 30/43; H10D 62/10; H10D 62/13; H10D 84/01

(52) U.S. Cl. CPC H10D 84/856; H10D 30/43; H10D 30/502; H10D 62/121; H10D 62/151; H10D 84/851; H10W 90/00; H10D 30/014; H10D 30/019; H10D 84/017; H10D 84/0186; H10W 72/923; H10W 72/934; H10W 72/952; H10W 90/792

(57) ABSTRACT

According to the embodiment of the present invention, a semiconductor device includes a first nanodevice including a plurality of first upper transistors and a plurality of first lower transistors. The first nanodevice includes a first upper source/drain and a first lower source/drain that are offset from each other across the plurality of first upper transistors and the plurality of first lower transistors. The first upper source/drain includes a frontside surface and a backside surface and the first lower source/drain includes two separate horizontal frontside surfaces and a vertical inner sidewall. The vertical inner sidewall is located between the two separate horizontal frontside surfaces. A silicide layer is contiguous and conformal with the two separate horizontal frontside surfaces and the vertical inner sidewall.

### BACKGROUND

The present invention relates generally to the field of microelectronics, and more particularly to a semiconductor device structure, and a method for forming a semiconductor device.

A nanosheet (NS) is the lead device architecture in continuing CMOS scaling. However, nanosheet technology has shown issues when scaling down such that as the devices become smaller and closer together, they are interfering with each other. Furthermore, as the devices become smaller and closer together, forming the connections to a backside power network is becoming more difficult.

### SUMMARY

According to the embodiment of the present invention, a semiconductor device includes a first nanodevice including a plurality of first upper transistors and a plurality of first lower transistors. The first nanodevice includes a first upper source/drain and a first lower source/drain that are offset from each other across the plurality of first upper transistors and the plurality of first lower transistors. The first upper source/drain includes a frontside surface and a backside surface and the first lower source/drain includes two separate horizontal frontside surfaces and a vertical inner sidewall. The vertical inner sidewall is located between the two separate horizontal frontside surfaces. A silicide layer is contiguous and conformal with the two separate horizontal frontside surfaces and the vertical inner sidewall.

According to the embodiment of the present invention, a semiconductor device includes a first nanodevice including a plurality of first upper transistors and a plurality of first lower transistors. The first nanodevice includes a first upper source/drain and a first lower source/drain that are offset from each other across the plurality of first upper transistors and the plurality of first lower transistors. The first upper source/drain includes a frontside surface and a backside surface and the first lower source/drain includes two separate horizontal frontside surfaces and a vertical inner sidewall. The vertical inner sidewall is located between the two separate horizontal frontside surfaces. A second nanodevice includes a plurality of second upper transistors and a plurality of second lower transistors. The second nanodevice is located adjacent to and parallel to the first nanodevice along an x-axis. The second nanodevice includes a second upper source/drain and a second lower source/drain that are offset from each other across the plurality of second upper transistors and the plurality of second lower transistors. A silicide layer is contiguous and conformal with the two separate horizontal frontside surfaces and the vertical inner sidewall.

According to the embodiment of the present invention, a semiconductor device includes a first nanodevice including a plurality of first upper transistors and a plurality of first lower transistors. The first nanodevice includes a first upper source/drain and a first lower source/drain that are offset from each other across the plurality of first upper transistors and the plurality of first lower transistors. The first upper source/drain includes a frontside surface and a backside surface and the first lower source/drain includes two separate horizontal frontside surfaces and a vertical inner sidewall. The vertical inner sidewall is located between the two separate horizontal frontside surfaces. A second nanodevice includes a plurality of second upper transistors and a plurality of second lower transistors. The second nanodevice is located adjacent to and parallel to the first nanodevice along an x-axis. The second nanodevice includes a second upper source/drain and a second lower source/drain that are offset from each other across the plurality of second upper transistors and the plurality of second lower transistors. A silicide layer is contiguous and conformal with the two separate horizontal frontside surfaces and the vertical inner sidewall. A backside source/drain contact connects to a backside surface of the second lower source/drain.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a top-down view of a plurality of nanodevices, in accordance with the embodiment of the present invention.

FIGS. 2-4 illustrate cross sections X₁, Y₁, and Y₂, respectively, of the plurality of nanodevices after nanosheet formation, shallow trench isolation (STI) region formation, gate formation, gate cut dielectric liner formation, source/drain formation, etch stop layer formation, gate cut dielectric pillar formation, lower dielectric liner formation, and CMP, in accordance with the embodiment of the present invention.

FIGS. 5-7 illustrate cross sections X₁, Y₁, and Y₂, respectively, of the plurality of nanodevices after the formation of a first trench and a second trench, in accordance with the embodiment of the present invention.

FIGS. 8-10 illustrate cross sections X₁, Y₁, and Y₂, respectively, of the plurality of nanodevices after the formation of a lower interlayer dielectric (ILD), in accordance with the embodiment of the present invention.

FIGS. 11-13 illustrate cross sections X₁, Y₁, and Y₂, respectively, of the plurality of nanodevices after the formation of a third trench and a fourth trench, in accordance with the embodiment of the present invention.

FIGS. 14-16 illustrate cross sections X₁, Y₁, and Y₂, respectively, of the plurality of nanodevices after the formation of a sacrificial layer, in accordance with the embodiment of the present invention.

FIGS. 17-19 illustrate cross sections X₁, Y₁, and Y₂, respectively, of the plurality of nanodevices after the formation of an additional ILD, in accordance with the embodiment of the present invention.

FIGS. 20-22 illustrate cross sections X₁, Y₁, and Y₂, respectively, of the plurality of nanodevices after the formation of a plurality of dielectric liners and a sacrificial material core, in accordance with the embodiment of the present invention.

FIGS. 23-26 illustrate cross sections X₁, X₂, Y₁, and Y₂, respectively, of the plurality of nanodevices after the formation of a bonding oxide layer, a first upper nanosheet, a second upper nanosheet, a third upper nanosheet, a first upper source/drain, a second upper source/drain, a third upper source/drain, an upper gate cut dielectric liner, an upper gate, an upper dielectric liner, an upper ILD, a first upper gate cut dielectric pillar, and a second gate cut dielectric pillar, in accordance with the embodiment of the present invention.

FIGS. 27-30 illustrate cross sections X₁, X₂, Y₁, and Y₂, respectively, of the plurality of nanodevices after the formation of a fifth trench and a sixth trench, in accordance with the embodiment of the present invention.

FIGS. 31-34 illustrate cross sections X₁, X₂, Y₁, and Y₂, respectively, of the plurality of nanodevices after the formation of a seventh trench, an eighth trench, and a ninth trench, in accordance with the embodiment of the present invention.

FIGS. 35-38 illustrate cross sections X₁, X₂, Y₁, and Y₂, respectively, of the plurality of nanodevices after the formation of a tenth trench, an eleventh trench, a twelfth trench, and a thirteenth trench, in accordance with the embodiment of the present invention.

FIGS. 39-42 illustrate cross sections X₁, X₂, Y₁, and Y₂, respectively, of the plurality of nanodevices after the formation of a first frontside source/drain contact, a second frontside source/drain contact, a third frontside source/drain contact, a first lower source/drain contact, a second lower source/drain contact, a first gate contact, and a second gate contact, in accordance with the embodiment of the present invention.

FIGS. 43-46 illustrate cross sections X₁, X₂, Y₁, and Y₂, respectively, of the plurality of nanodevices after the formation of a plurality of silicide layers, in accordance with the embodiment of the present invention.

FIGS. 47-50 illustrate cross sections X₁, X₂, Y₁, and Y₂, respectively, of the plurality of nanodevices after the formation of a back-end-of-line (BEOL) layer, and bonding to a carrier wafer, in accordance with the embodiment of the present invention.

FIGS. 51-54 illustrate cross sections X₁, X₂, Y₁, and Y₂, respectively, of the plurality of nanodevices after the carrier wafer is flipped and the substrate is removed, and after the formation of a backside ILD (BILD) layer, a first backside source/drain contact, a second backside source/drain contact, an upper source/drain contact, and a backside interconnect, in accordance with the embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

References in the specification to “one embodiment,” “an embodiment,” “an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “formed on,” or “formed atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be a direct or indirect positional relationship. As an example of an indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes which are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

The design of a staggered stacked field effect transistor (FET) is often a compromise between achieving a small cell height and obtaining a reliable architecture where the source/drain contacts do not short to unintended structures. It is difficult to form a top source/drain connected to a backside of the device and a bottom source/drain connected to a frontside of the device within the same cell. Currently, there is no clear fabrication pathway and viable structure existing for source/drain contacts that is readily compatible with the structure of vertically stacked FET devices while providing a large contact area.

By employing a source/drain gouge and a large-area silicide layer, an effective frontside source/drain contact to bottom source/drain may be achieved without having a propensity for source/drain-gate shorts or impeding device performance. Thus, the source/drain gouge and large-area silicide layer may enable a robust and reliable fabrication process. The present invention does not require that all advantages need to be incorporated into every embodiment of the invention.

The present invention is directed to forming a staggered stacked FET such that active regions of upper and lower transistors are offset from each other. The staggered stacked FET is formed through a multistage processing, where the first stage forms a gouge by etching a portion of a lower source/drain. The second stage forms a lower interlayer dielectric (ILD) within the gouge, atop the lower source/drain, and around sidewalls of the lower source/drain, and then removes a portion of the lower ILD within the gouge and around a portion of sidewalls of the lower source/drain. The third stage forms a sacrificial layer extending along exposed portions of the lower source/drain and forms an additional ILD surrounding exposed portions of the sacrificial layer. The fourth stage forms a dielectric liner extending along an outer sidewall of the lower source/drain, a sacrificial material core extending along an outer sidewall of the dielectric liner, and another dielectric liner extending along an outer sidewall of the sacrificial material core. The fifth stage forms an upper source/drain above the sacrificial material core and the dielectric liner. The sixth stage forms a trench by removing a portion of an upper ILD, the lower ILD, a bonding oxide layer, and the sacrificial layer. The seventh stage fills the trench with a conductive metal, forming a lower source/drain contact. The eighth stage forms a silicide layer contiguous and conformal with at least three sides of the lower source/drain. The ninth stage forms an upper source/drain contact connected to a backside surface of the upper source/drain.

As used herein, the term “inner sidewall” refers to a sidewall closest to a center of the cross section and the term “outer sidewall” refers to a sidewall closest to an edge of the cross section.

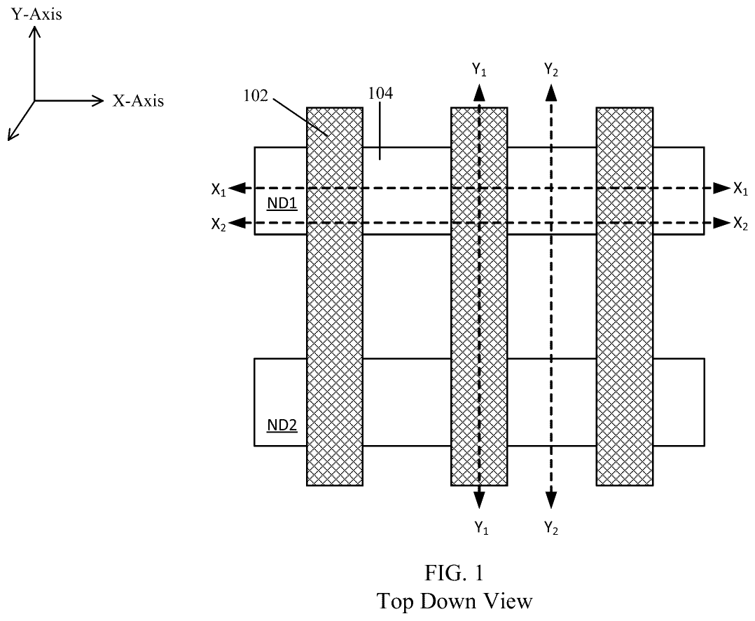

FIG. 1 illustrates a top-down view of a plurality of nanodevices ND1, ND2, in accordance with the embodiment of the present invention. The adjacent and parallel devices along an x-axis include a first nanodevice ND1 including a plurality of first upper transistors and a plurality of first lower transistors, and a second nanodevice ND2 including a plurality of second upper transistors and a plurality of second lower transistors. Cross-section X₁ is a cross section perpendicular to the gates along a first horizontal axis of the first nanodevice ND1. Cross-section X₂ is a cross section perpendicular to the gates along a second horizontal axis of the first nanodevice ND1. Cross-section Y₁ is a cross section parallel to the gates in the gate region 102 across the plurality of nanodevices ND1, ND2. Cross-section Y₂ is a cross section parallel to the gates in the source/drain region 104 across the plurality of nanodevices ND1, ND2. It may be appreciated that the embodiment of the present invention is not limited to nanodevices ND1, ND2 and that other devices including, but not limited to, nanosheet transistors, FinFET, nanowire, and a planar device may also be used.

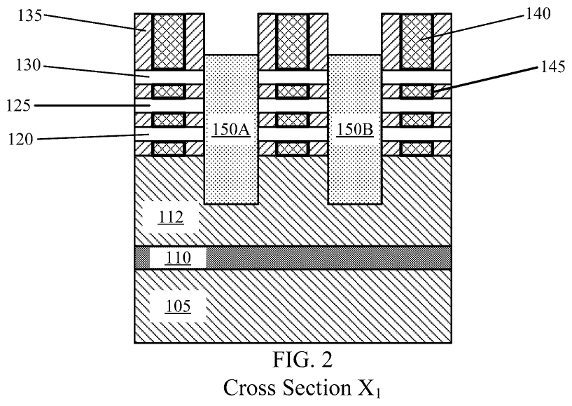

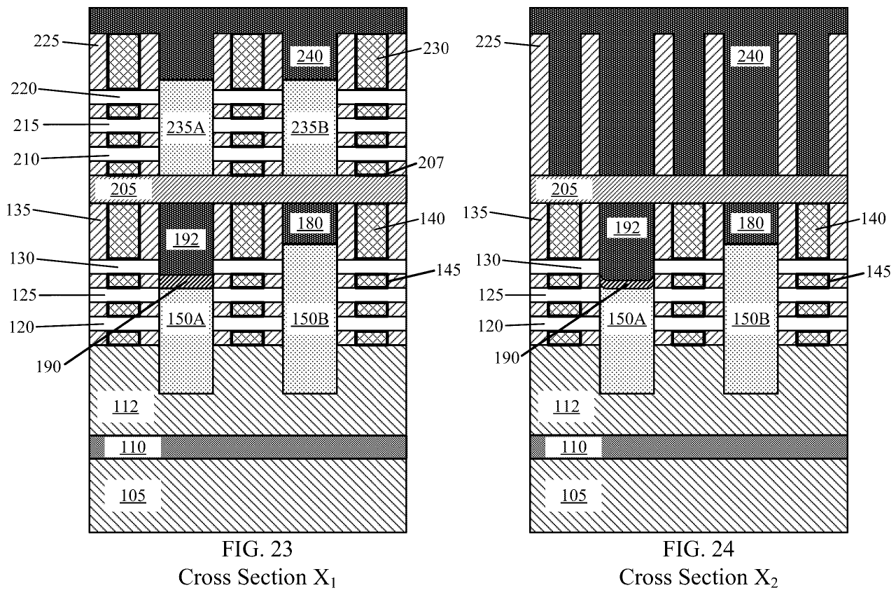

FIGS. 2-4 illustrate cross sections X₁, Y₁, and Y₂, respectively, of the plurality of nanodevices ND1, ND2 after nanosheet 120, 125, 130 formation, shallow trench isolation (STI) region 114 formation, gate 140 formation, gate cut dielectric liner 135 formation, lower source/drain 150A, 150B, 150C formation, etch stop layer 110 formation, gate cut dielectric pillar 155, 160, 165 formation, lower dielectric liner 145 formation, and CMP, in accordance with the embodiment of the present invention. The plurality of nanodevices ND1, ND2 include a substrate 105, an etch stop layer 110, an underlying substrate layer 112, an STI region 114, a first lower nanosheet 120, a second lower nanosheet 125, and a third lower upper nanosheet 130. As used herein, the terms “upper” and “lower” refer to the orientation of structures prior to a wafer flip. Thus, structures above a bonding oxide layer 205 (FIGS. 23-26) prior to the wafer flip are referred to as “upper” and structures below the bonding oxide layer 205 (FIGS. 23-26) prior to the wafer flip are referred to as “lower.” The substrate 105 and the etch stop layer 110 can be, for example, a material including, but not necessarily limited to, silicon (Si), silicon germanium (SiGe), Si:C (carbon doped silicon), carbon doped silicon germanium (SiGe: C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 and the etch stop layer 110 may be doped, undoped or contain doped regions and undoped regions therein.

The first sacrificial layer (not shown) is formed directly atop the underlying substrate layer 112. The second sacrificial layer (not shown) is formed directly atop the first sacrificial layer (not shown). The first lower nanosheet 120 is formed directly atop the second sacrificial layer (not shown). The third sacrificial layer (not shown) is formed directly atop the first lower nanosheet 120. The second lower nanosheet 125 is formed directly atop the third sacrificial layer (not shown). The fourth sacrificial layer (not shown) is formed directly atop the second lower nanosheet 125. The third lower nanosheet 130 is formed directly atop the fourth sacrificial layer (not shown). The first sacrificial layer (not shown), the second sacrificial layer (not shown), the third sacrificial layer (not shown), and the fourth sacrificial layer (not shown) are hereinafter referred to as the plurality of sacrificial layers (not shown). In addition, the first lower nanosheet 120, the second lower nanosheet 125, and the third lower nanosheet 130 are hereinafter referred to as the plurality of lower nanosheets 120, 125, 130. The plurality of sacrificial layers (not shown) may be comprised of, for example, SiGe, where Ge is about 35%. The plurality of lower nanosheets 120, 125, 130 may be comprised of, for example, Si. The number of nanosheets and the number of sacrificial layers described above are not intended to be limiting, and it may be appreciated that in the embodiment of the present invention the number of nanosheets and the number of sacrificial layers may vary. After formation of the plurality of lower nanosheets 120, 125, 130 and the plurality of sacrificial layers (not shown), together the nanosheet stack, the nanosheet stack (comprising alternative Si and SiGe layers) may be further patterned using conventional lithography and etching processes. After nanosheet stack formation and patterning, the STI region 114 is formed by dielectric filling, CMP, and dielectric recess.

A dummy gate material is deposited and then patterned to form dummy gates (not shown), followed by gate cut dielectric liner 135 formation by a conformal dielectric liner deposition followed by anisotropic etch. The gate cut dielectric liner 135 may be comprised of, for example, SiN. Then, the first lower source/drain 150A, the second lower source/drain 150B, and the third lower source/drain 150C are epitaxially grown over exposed sidewalls of the plurality of lower nanosheets 120, 125, 130 followed by CMP to remove a dummy gate hard mask (not shown). Then, the sacrificial layers (not shown) are removed, followed by gate 140 formation. The first lower source/drain 150A, the second lower source/drain 150B, and the third lower source/drain 150C are formed directly atop recessed portions of the underlying substrate layer 112.

The first lower source/drain 150A, the second lower source/drain 150B, and the third lower source/drain 150C can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

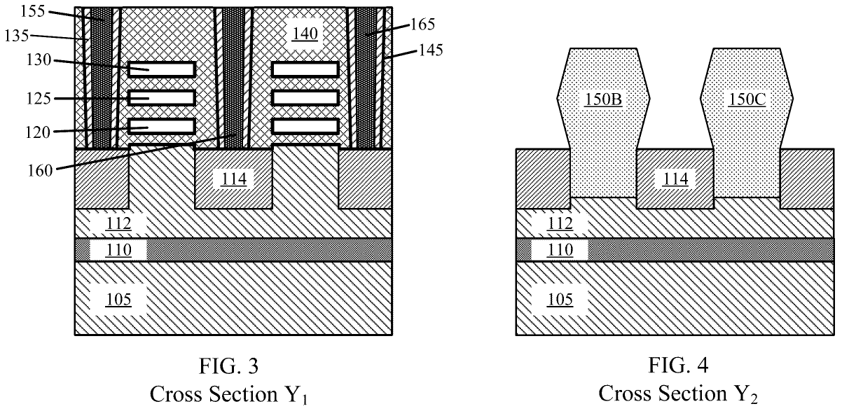

In FIG. 2, a gate material is deposited in the space created by the removal of the plurality of sacrificial layers (not shown) and directly atop the third lower nanosheet 130 to form a replacement gate (i.e., the gate 140). In FIG. 3, the gate material is deposited in the space created by the removal of the plurality of sacrificial layers (not shown), and directly atop the third lower nanosheet 130 and the STI region 114 to form the gate 140. The gate 140 can be comprised of, for example, a gate dielectric liner, such as a high-k dielectric like HfO2, ZrO2, HfLaOx, etc., and work function layers, such as TiN, TiAlC, TiC, etc., and conductive metal fills, like W. A liner material is also deposited in trenches (not shown) formed during front-end-of-line processing to form the first gate cut dielectric pillar 155, the second gate cut dielectric pillar 160, and the third gate cut dielectric pillar 165. The liner material may be comprised of, for example, SiN, SiBCN, SiOCN, SiOC, SiO₂, or SiC. In FIGS. 2-3, an additional liner material is deposited in trenches (not shown) formed during front-end-of-line processing to form the lower dielectric liner 145 surrounding edges of the gate 140. The lower dielectric liner 145 may be comprised of, for example, HfO₂.

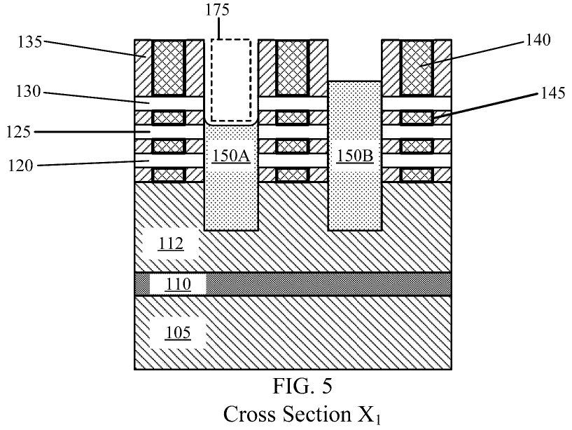

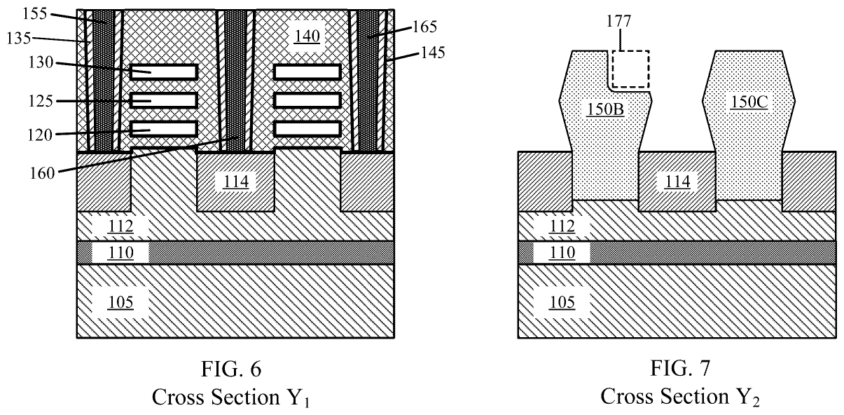

FIGS. 5-7 illustrate cross sections X₁, Y₁, and Y₂, respectively, of the plurality of nanodevices ND1, ND2 after the formation of a first trench 175 and a second trench 177, in accordance with the embodiment of the present invention. In FIG. 5, a portion of the first lower source/drain 150A is etched by, for example, RIE to form the first trench 175. A bottom surface of the first trench 175 exposes a top surface of the first lower source/drain 150A. In FIG. 7, a portion of the second lower source/drain 150B is etched by, for example, RIE to form the second trench 177. A bottom surface of the second trench 177 exposes a portion of a top surface of the second lower source/drain 150B.

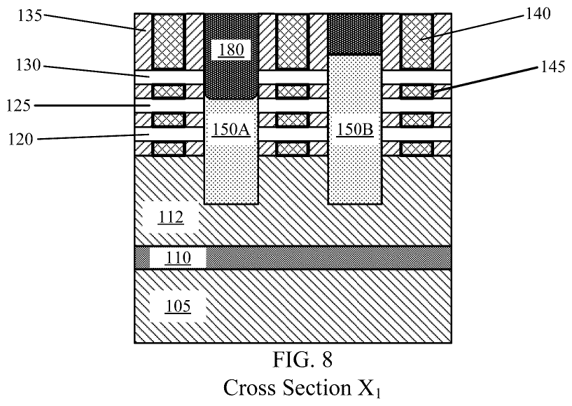

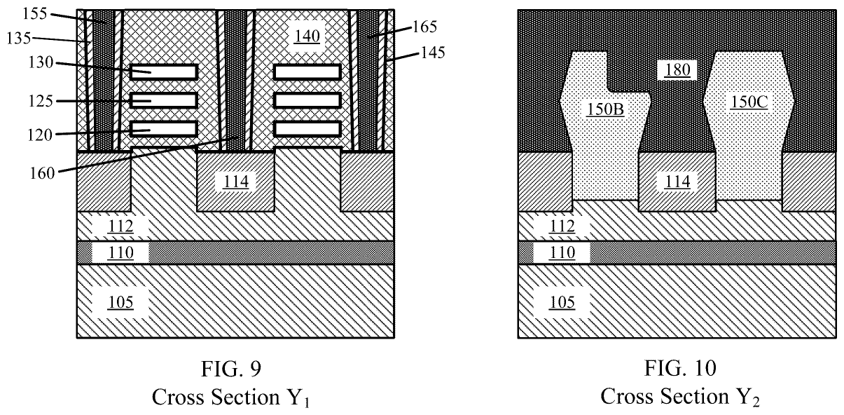

FIGS. 8-10 illustrate cross sections X₁, Y₁, and Y₂, respectively, of the plurality of nanodevices ND1, ND2 after the formation of a lower interlayer dielectric (ILD) 180, in accordance with the embodiment of the present invention. In FIG. 8, the lower ILD 180 is formed directly atop the first lower source/drain 150A and the second lower source/drain 150B. In FIG. 10, the lower ILD 180 is formed directly atop the STI region 114, the second lower source/drain 150B, and the third lower source/drain 150C.

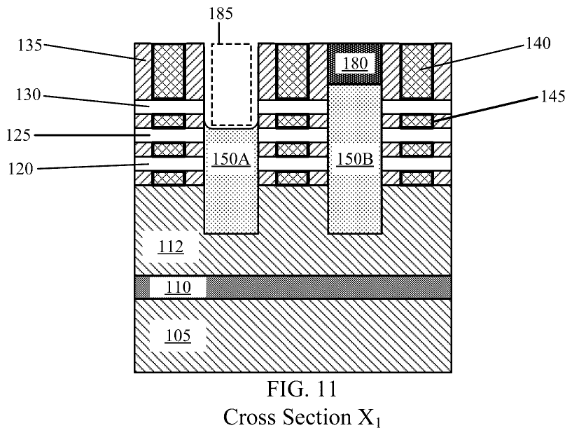

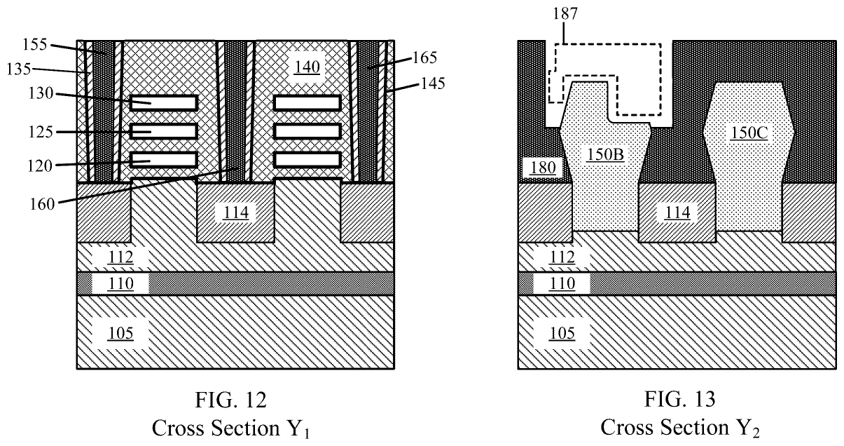

FIGS. 11-13 illustrate cross sections X₁, Y₁, and Y₂, respectively, of the plurality of nanodevices ND1, ND2 after the formation of a third trench 185 and a fourth trench 187, in accordance with the embodiment of the present invention. In FIG. 11, a portion of the lower ILD 180 is etched by, for example, RIE to form the third trench 185. A bottom surface of the third trench 185 exposes the top surface of the first lower source/drain 150A. In FIG. 13, a portion of the lower ILD 180 is etched by, for example, RIE to form the fourth trench 187. A bottom surface of the fourth trench 187 exposes a top surface and a portion of sidewalls of the second lower source/drain 150B.

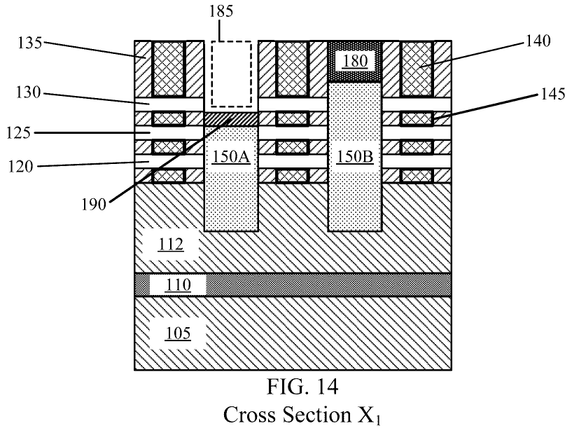

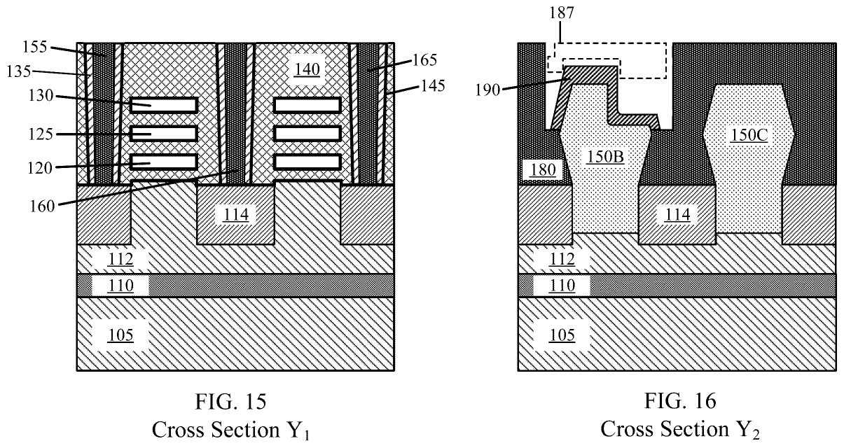

FIGS. 14-16 illustrate cross sections X₁, Y₁, and Y₂, respectively, of the plurality of nanodevices ND1, ND2 after the formation of a sacrificial layer 190, in accordance with the embodiment of the present invention. In FIG. 14, the sacrificial layer 190 is formed directly atop the first lower source/drain 150A. In FIG. 16, the sacrificial layer 190 is formed directly atop the second lower source/drain 150B and extends along exposed portions of the second lower source/drain 150B.

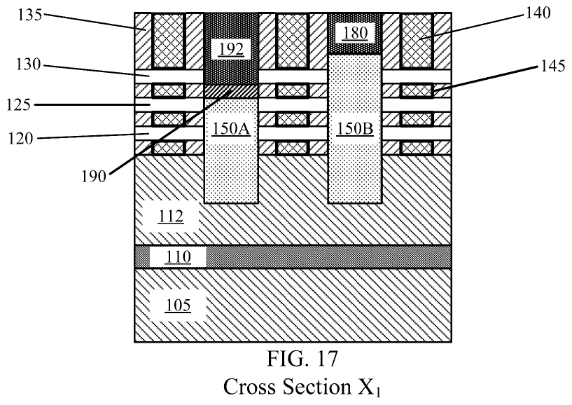

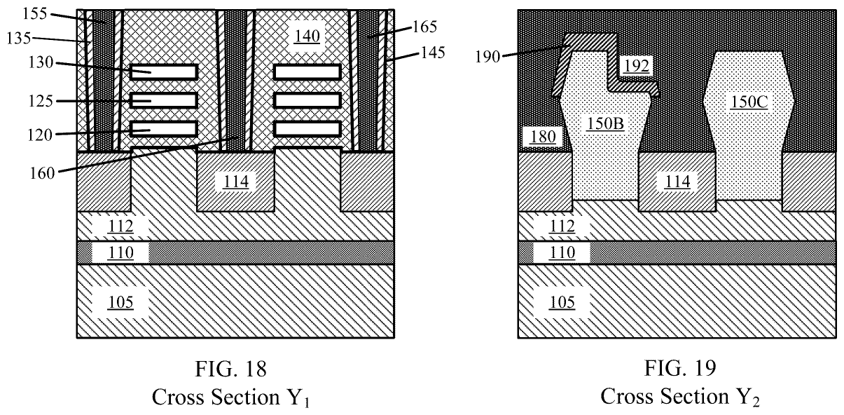

FIGS. 17-19 illustrate cross sections X₁, Y₁, and Y₂, respectively, of the plurality of nanodevices ND1, ND2 after the formation of an additional ILD 192, in accordance with the embodiment of the present invention. In FIG. 17, the additional ILD 192 is formed directly atop the sacrificial layer 190. In FIG. 19, the additional ILD 192 is formed directly atop the sacrificial layer 190 and surrounds exposed portions of the sacrificial layer 190. In FIGS. 17 and 19, a portion of the additional ILD 192 is selectively removed by, for example, CMP.

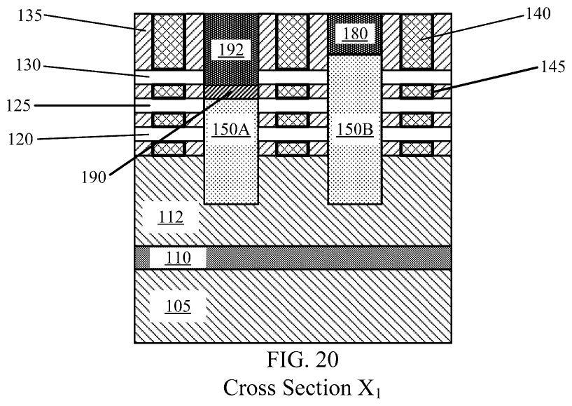

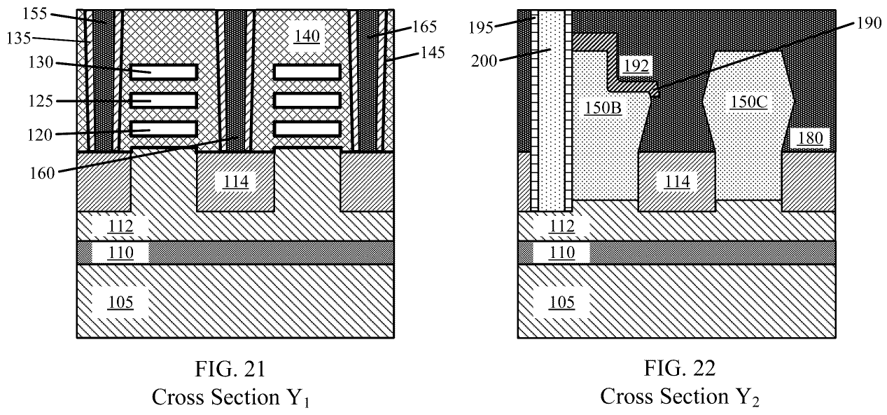

FIGS. 20-22 illustrate cross sections X₁, Y₁, and Y₂, respectively, of the plurality of nanodevices ND1, ND2 after the formation of a plurality of dielectric liners 195 and a sacrificial material core 200, in accordance with the embodiment of the present invention. A first dielectric liner of the plurality of dielectric liners 195 extends along an outer sidewall of the second lower source/drain 150B, the sacrificial material core 200 extends along an outer sidewall of the first dielectric liner, and another dielectric liner of the plurality of dielectric liners 195 extends along an outer sidewall of the sacrificial material core 200.

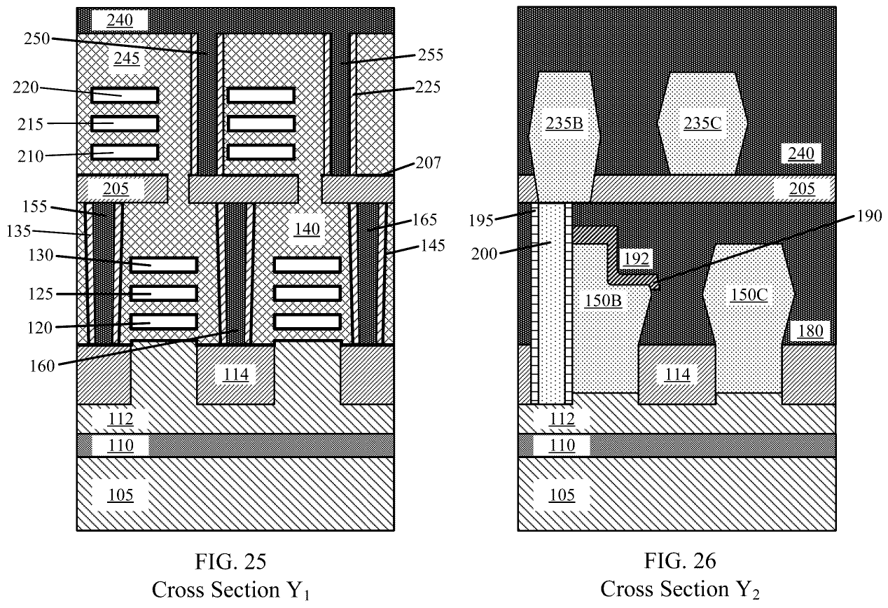

FIGS. 23-26 illustrate cross sections X₁, X₂, Y₁, and Y₂, respectively, of the plurality of nanodevices ND1, ND2 after the formation of a bonding oxide layer 205, a first upper nanosheet 210, a second upper nanosheet 215, a third upper nanosheet 220, a first upper source/drain 235A, a second upper source/drain 235B, a third upper source/drain 235C, an upper gate cut dielectric liner 225, an upper gate 245, an upper dielectric liner 207, an upper ILD 240, a first upper gate cut dielectric pillar 250, and a second gate cut dielectric pillar 255, in accordance with the embodiment of the present invention. In FIGS. 23-24, the bonding oxide layer 205 is formed directly atop the gate cut dielectric liner 135, the gate 140, the lower ILD 180, and the additional ILD 192. In FIG. 25, the bonding oxide layer 205 is formed directly atop the gate cut dielectric liner 135, the gate 140, the first gate cute dielectric pillar 155, the second gate cut dielectric pillar 160, and the third gate cut dielectric pillar 165. In FIG. 26, the bonding oxide layer 205 is formed directly atop the lower ILD 180, the plurality of dielectric liners 195, and the sacrificial material core 200. In FIGS. 23-26, the first upper nanosheet 210, the second upper nanosheet 215, the third upper nanosheet 220, the first upper source/drain 235A, the second upper source/drain 235B, the third upper source/drain 235C, the upper gate cut dielectric liner 225, the upper gate 245, the upper dielectric liner 207, the upper ILD 240, the first upper gate cut dielectric pillar 250, and the second gate cut dielectric pillar 255 are formed in a similar manner to that described above with respect to the description of FIGS. 2-4.

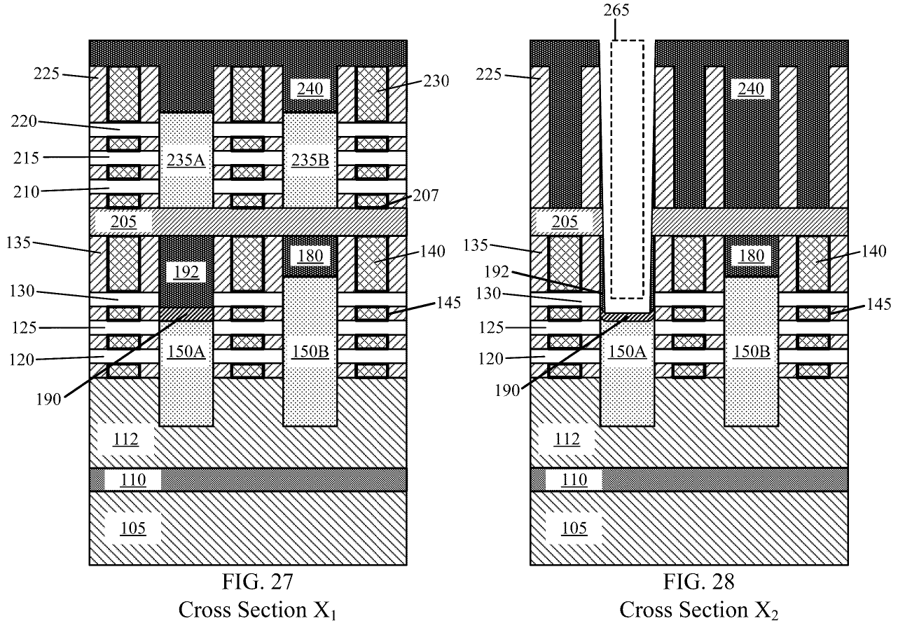

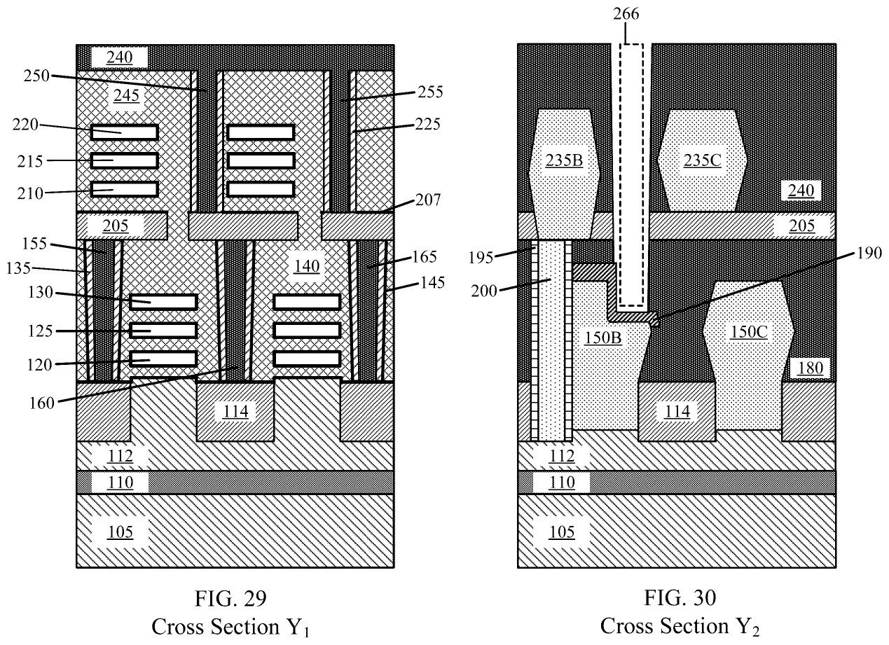

FIGS. 27-30 illustrate cross sections X₁, X₂, Y₁, and Y₂, respectively, of the plurality of nanodevices ND1, ND2 after the formation of a fifth trench 265 and a sixth trench 266, in accordance with the embodiment of the present invention. A portion of the upper ILD 240, the bonding oxide layer 205, and the additional ILD 192 is etched by, for example, RIE to form the fifth trench 265 and the sixth trench 266. A bottom surface of the fifth trench 265 and the sixth trench 266 exposes a top surface of the sacrificial layer 190.

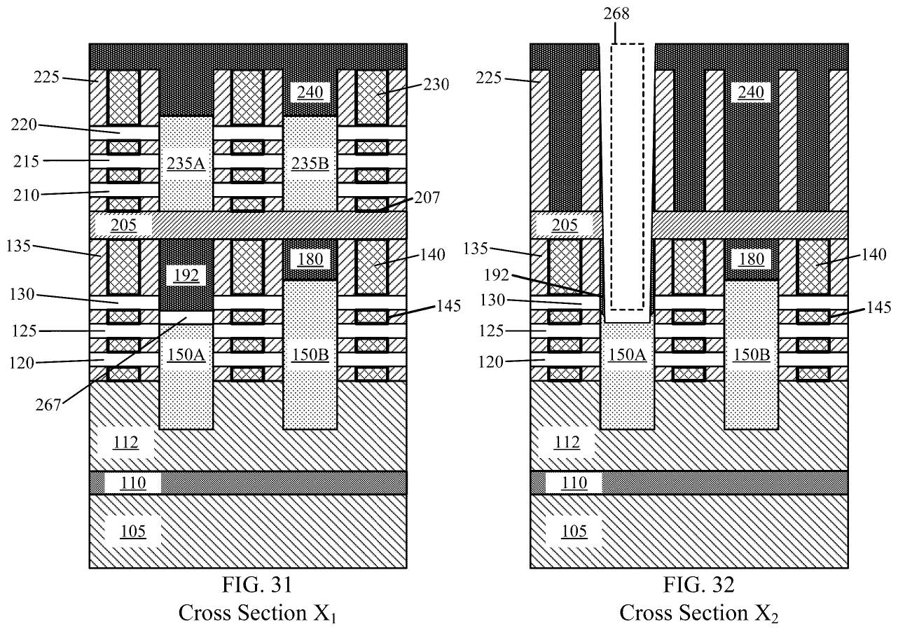

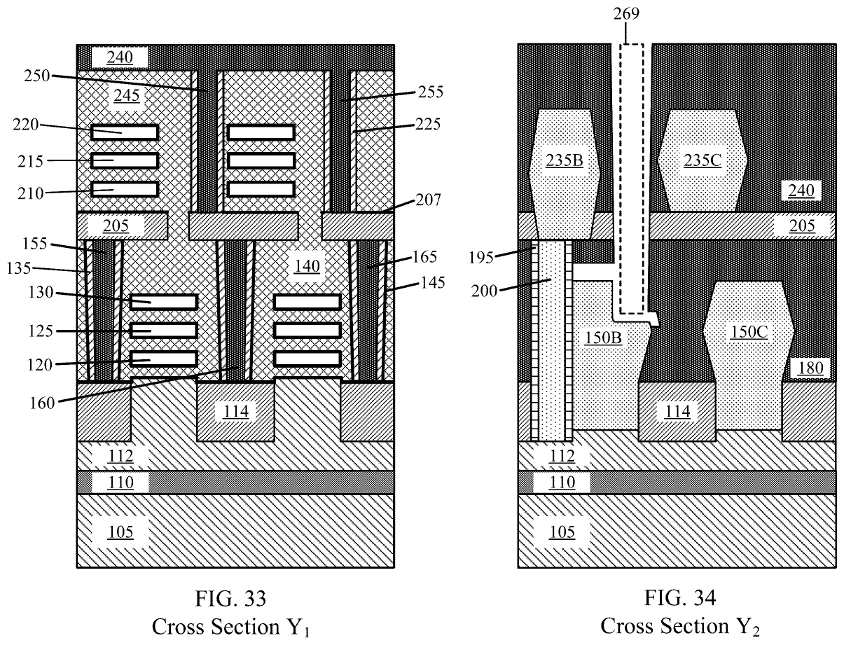

FIGS. 31-34 illustrate cross sections X₁, X₂, Y₁, and Y₂, respectively, of the plurality of nanodevices ND1, ND2 after the formation of a seventh trench 267, an eighth trench 268, and a ninth trench 269, in accordance with the embodiment of the present invention. The sacrificial layer 190 is etched by, for example, RIE to form the seventh trench 267, the eighth trench 268, and the ninth trench 269. In FIGS. 31-32, a bottom surface of the seventh trench 267 and the eighth trench 268 exposes a top surface of the first lower source/drain 150A. In FIG. 34, a bottom surface of the ninth trench 269 exposes a top surface of the second lower source/drain 150B.

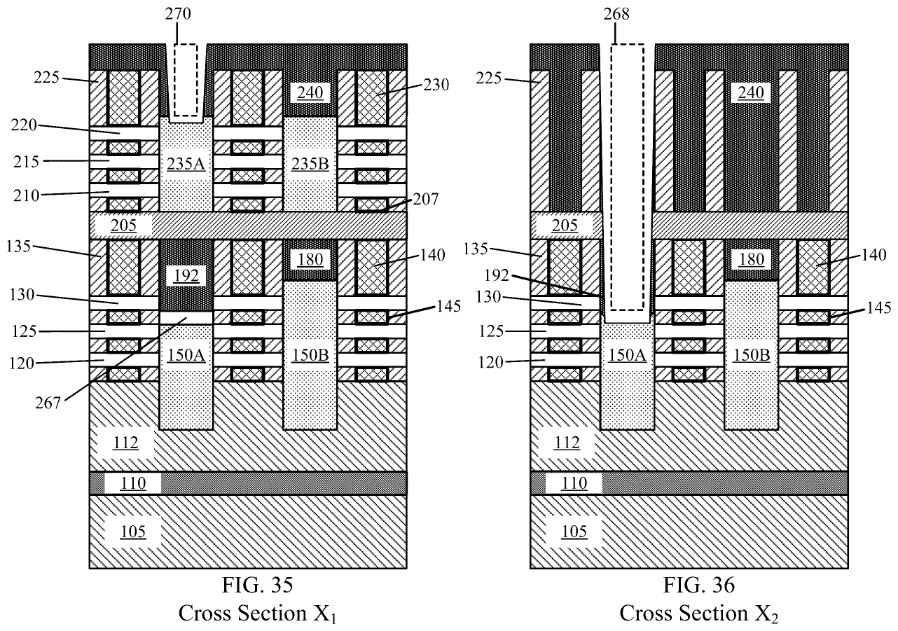

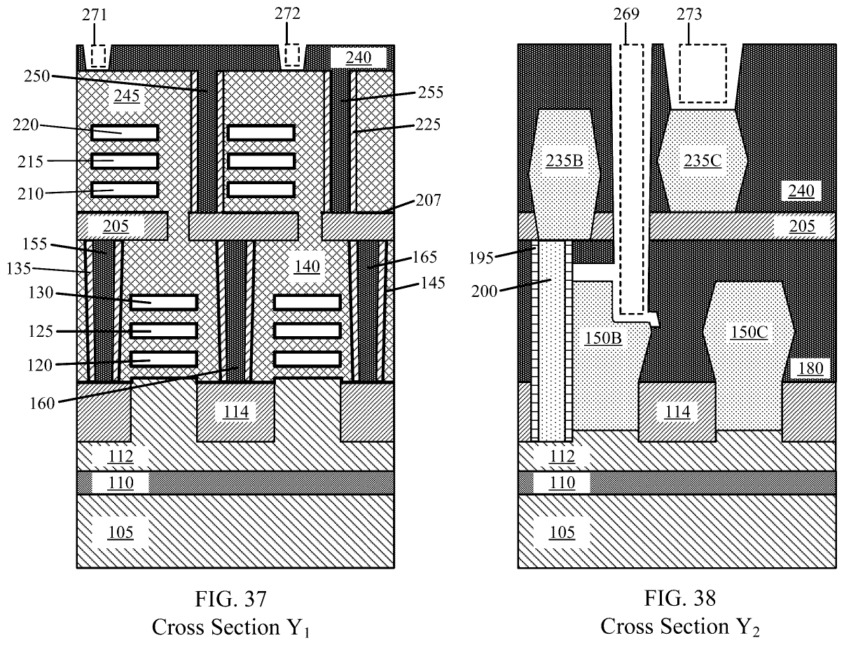

FIGS. 35-38 illustrate cross sections X₁, X₂, Y₁, and Y₂, respectively, of the plurality of nanodevices ND1, ND2 after the formation of a tenth trench 270, an eleventh trench 271, a twelfth trench 272, and a thirteenth trench 273, in accordance with the embodiment of the present invention. In FIG. 35, a portion of the upper ILD 240 and the first upper source/drain 235A are etched by, for example, RIE to form the tenth trench 270. A bottom surface of the tenth trench 270 exposes a portion of a top surface of the first upper source/drain 235A. In FIG. 37, different portions of the upper ILD 240 are etched by, for example, RIE, to form the eleventh trench 271 and the twelfth trench 272. Bottom surfaces of the eleventh trench 271 and the twelfth trench 272 expose portions of a top surface of the upper gate 245. In FIG. 38, a portion of the upper ILD is etched by, for example, RIE to form the thirteenth trench 273. A bottom surface of the thirteenth trench 273 exposes a top surface of the third upper source/drain 235C.

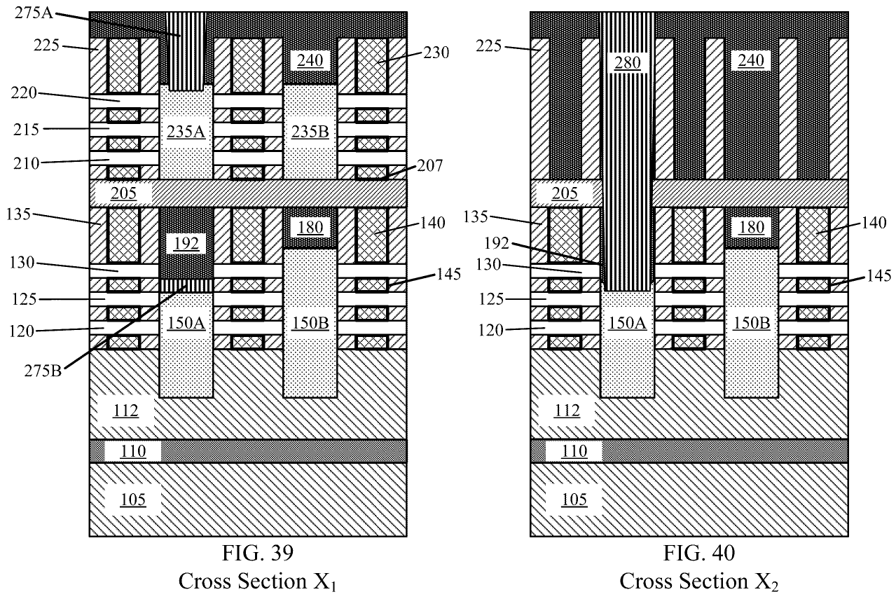

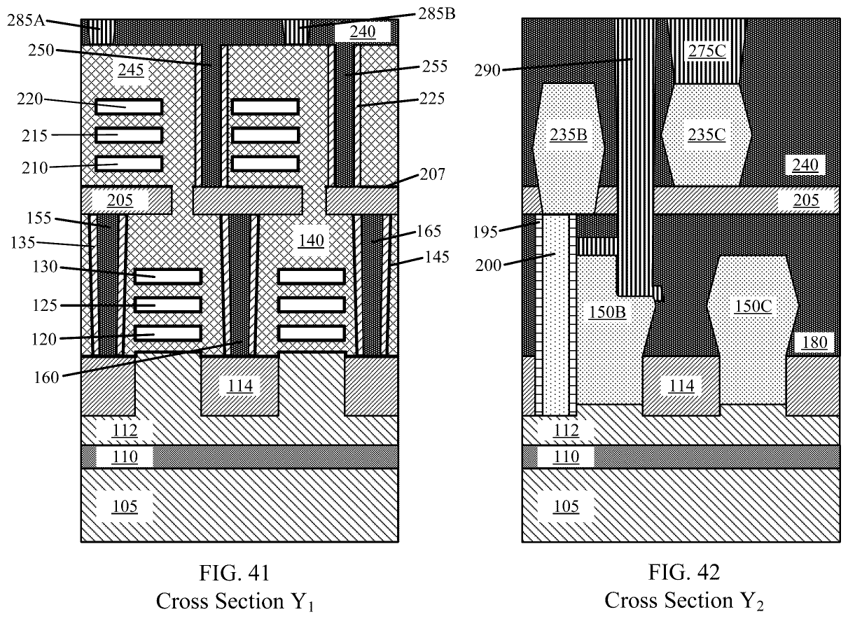

FIGS. 39-42 illustrate cross sections X₁, X₂, Y₁, and Y₂, respectively, of the plurality of nanodevices ND1, ND2 after the formation of a first frontside source/drain contact 275A, a second frontside source/drain contact 275B, a third frontside source/drain contact 275C, a first lower source/drain contact 280, a second lower source/drain contact 290, a first gate contact 285A, and a second gate contact 285B, in accordance with the embodiment of the present invention. In FIG. 39, the seventh trench 267 and the tenth trench 270 are filled with a conductive metal (e.g., including a silicide liner, such as Ni, Ti, NiPt, an adhesion metal liner, such as TiN and conductive metal fill, such as W, Co, or Ru) to form the first frontside source/drain contact 275A and the second frontside source/drain contact 275B. In FIG. 40, the eighth trench 268 is filled with the conductive metal to form the first lower source/drain contact 280. In FIG. 41, the eleventh trench 271 and the twelfth trench 272 are filled with the conductive metal to form the first gate contact 285A and the second gate contact 285B, respectively. In FIG. 42, the ninth trench 269 and the thirteenth trench 273 are filled with the conductive metal to form the second lower source/drain contact 290 and the third frontside source/drain contact 275C. The second lower source/drain contact 290 connects to at least three sides of the second lower source/drain 150B.

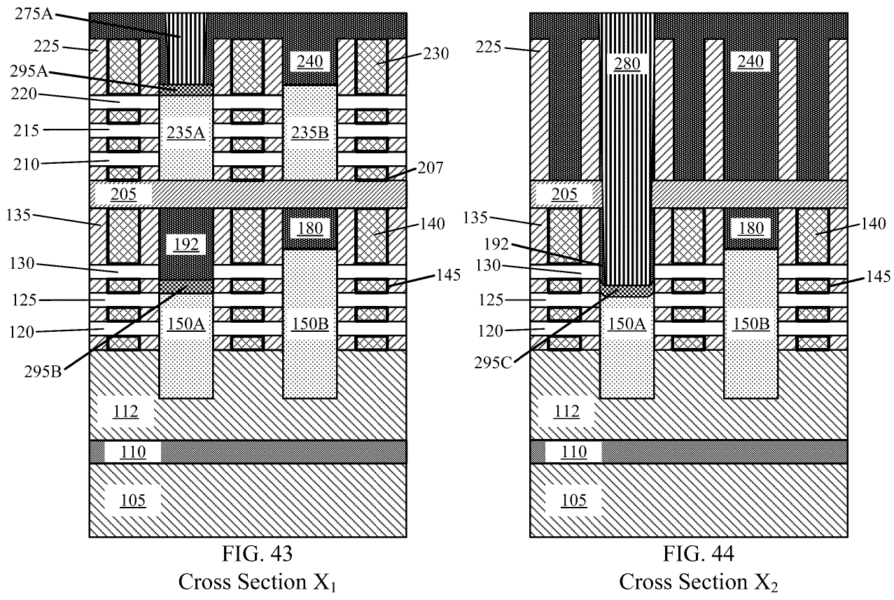

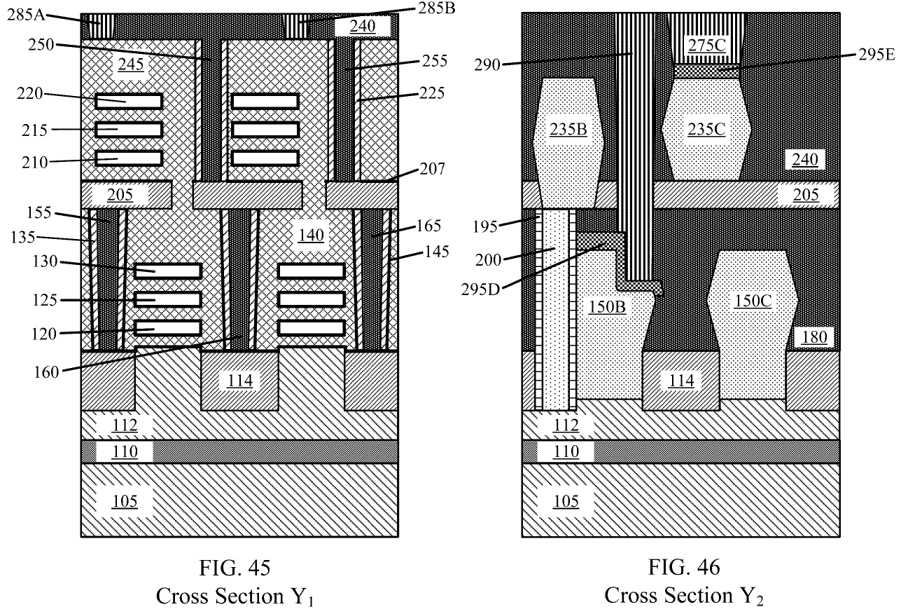

FIGS. 43-46 illustrate cross sections X₁, X₂, Y₁, and Y₂, respectively, of the plurality of nanodevices ND1, ND2 after the formation of a plurality of silicide layers 295A, 295B, 295C, 295D, 295E, in accordance with the embodiment of the present invention. As described above with respect to the description of FIGS. 39-42, the conductive metal includes a silicide liner, such as Ni, Ti, or NiPt. The silicide liner may form the plurality of silicide layers 295A, 295B, 295C, 295D, 295E. In FIG. 43, the first silicide layer 295A and the second silicide layer 295B are formed directly atop the first upper source/drain 235A and the first lower source/drain 150A, respectively. In FIG. 44, the third silicide layer 295C is formed directly atop the first lower source/drain 150A. In FIG. 46, the fourth silicide layer 295D and the fifth silicide layer 295E are formed directly atop the second lower source/drain 150B and the third upper source/drain 235C, respectively. The fourth silicide layer 295D connects to at least three sides of the second lower source/drain 150B.

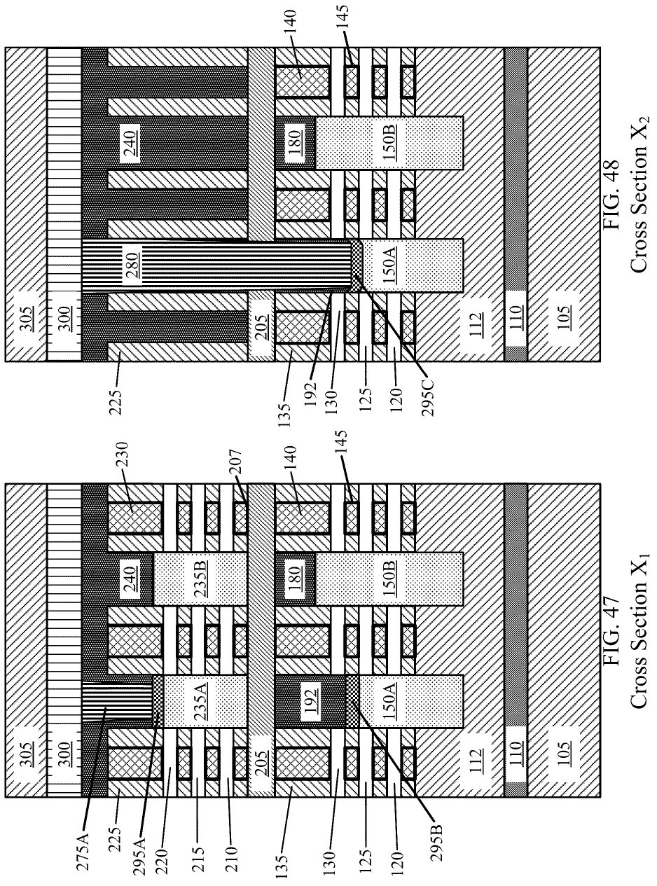

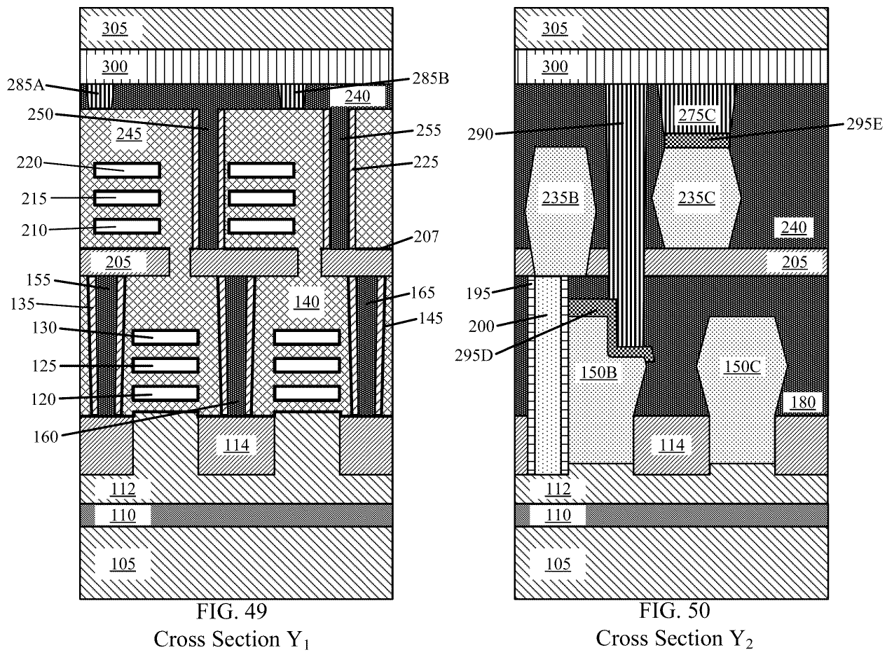

FIGS. 47-50 illustrate cross sections X₁, X₂, Y₁, and Y₂, respectively, of the plurality of nanodevices ND1, ND2 after the formation of a back-end-of-line (BEOL) layer 300, and bonding to a carrier wafer 305, in accordance with the embodiment of the present invention. The BEOL layer 205 may contain multiple metal layers and vias in between. In FIG. 47, the BEOL layer 300 is formed directly atop the upper ILD 240 and the first frontside source/drain contact 275A. In FIG. 48, the BEOL layer 300 is formed directly atop the first lower source/drain contact 280 and the upper ILD 240. In FIG. 49, the BEOL layer 300 is formed directly atop the first gate contact 285A, the second gate contact 285B, and the upper ILD 240. In FIG. 50, the BEOL layer 300 is formed directly atop the second lower source/drain contact 290, the third frontside source/drain contact 275C, and the upper ILD 240. In FIGS. 47-50, the carrier wafer 305 is formed directly atop the BEOL layer 300 by bonding processes (e.g., oxide-oxide bonding).

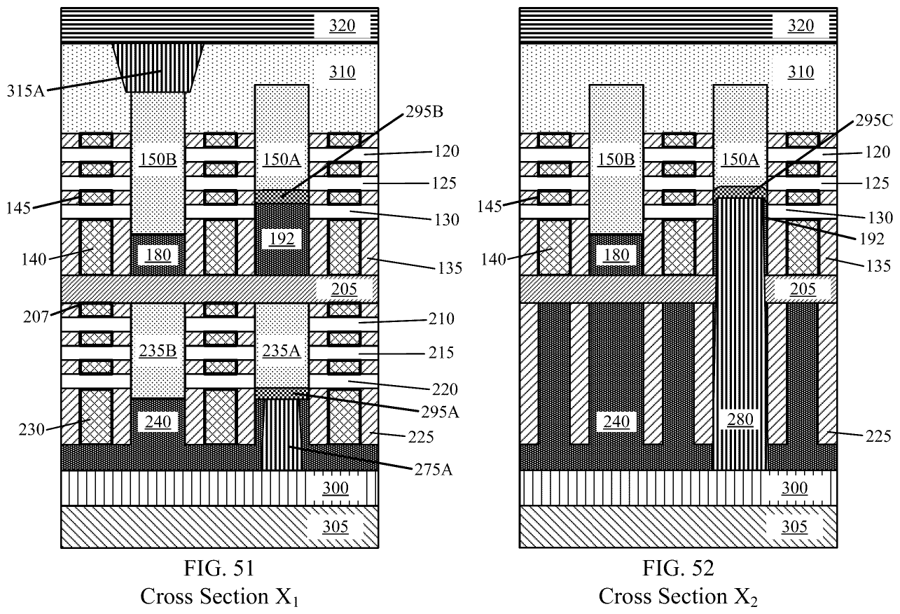

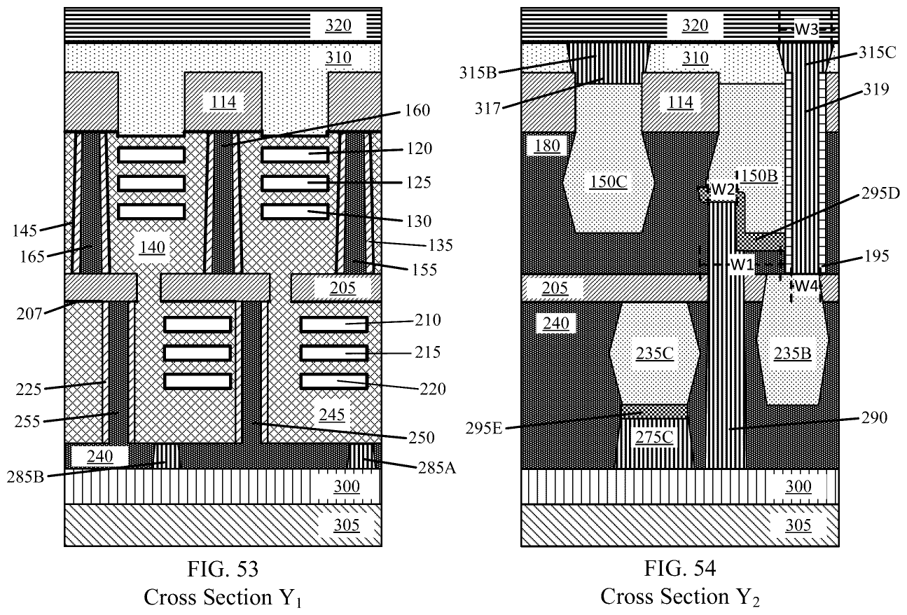

FIGS. 1-50 illustrate the processing of the frontside of the substrate 105, while FIGS. 51-54 illustrate the processing of the backside of the substrate 105. FIGS. 51-54 illustrate cross sections X₁, X₂, Y₁, and Y₂, respectively, of the plurality of nanodevices ND1, ND2 after the carrier wafer 305 is flipped and the substrate 105 is removed, and after the formation of a backside ILD (BILD) layer 310, a first backside source/drain contact 315A, a second backside source/drain contact 315B, 317, an upper source/drain contact 315C, 319, and a backside interconnect 320, in accordance with the embodiment of the present invention. The carrier wafer 305 is flipped and the carrier wafer 305 becomes a handler wafer. The substrate 105 is removed by, for example, a combination of processes such as wafer grinding, CMP, and/or selective dry/wet etch, stopping on the etch stop layer 110. The etch stop layer 110 is removed to expose the underlying substrate layer 112. The underlying substrate layer 112 is removed by, for example, a selective wet or dry etch process. The BILD layer 310 may be comprised of, for example, SiC or SiOC. In FIGS. 51-52, the BILD layer 310 is deposited directly atop the gate 140, the lower dielectric liner 145, the gate cut dielectric liner 135, the first lower source/drain 150A, and the second lower source/drain 150B. In FIG. 53, the BILD layer 310 is deposited directly atop the STI region 114 and the lower dielectric liner 145. In FIG. 54, the BILD layer 310 is deposited directly atop the STI region 114, the second lower source/drain 150B, the third lower source/drain 150C, the plurality of dielectric liners 195, and the sacrificial material core 200. In FIGS. 51-54, a portion of the BILD layer 310 is selectively removed by, for example, CMP, and a plurality of trenches (not shown) formed during back-end-of-line (BEOL) patterning are filled with a conductive metal (e.g., including a silicide liner, such as Ni, Ti, NiPt, an adhesion metal liner, such as TiN and conductive metal fill, such as W, Co, or Ru) to form the first backside source/drain contact 315A, the second backside source/drain contact 315B, 317, and the upper source/drain contact 315C, 319. The second backside source/drain contact 315B, 317 includes a first head section 315B and a first shaft section 317, where the shaft section 317 connects to a backside surface of the third lower source/drain 150C. In FIG. 51, the backside interconnect 320 is formed directly atop the BILD layer 310 and the first backside source/drain contact 315A. In FIGS. 52-53, the backside interconnect 320 is formed directly atop the BILD layer 310. In FIG. 54, the backside interconnect 320 is formed directly atop the BILD layer 310, the second backside source/drain contact 315B, 317 and the upper source/drain contact 315C, 319.

In FIGS. 51-54, the first nanodevice ND1 includes the second upper source/drain 235B (i.e., the first upper source/drain in the claims) and the second lower source/drain 150B (i.e., the first upper source/drain in the claims) that are offset (i.e., staggered) from each other across the plurality of first upper transistors and the plurality of first lower transistors. The second upper source/drain 235B includes a frontside surface and a backside surface and the second lower source/drain 150B includes two separate horizontal frontside surfaces and a vertical inner sidewall. The vertical inner sidewall is located between the two separate horizontal frontside surfaces. The second nanodevice ND2 includes the third upper source/drain 235C (i.e., the second upper source/drain in the claims) and the third lower source/drain 150C (i.e., the second lower source/drain in the claims) that are offset from each other across the plurality of second upper transistors and the plurality of second lower transistors.

The fourth silicide layer 295D (i.e., the silicide layer in the claims) is contiguous and conformal with the two separate horizontal frontside surfaces and the vertical inner sidewall. The second lower source/drain 150B includes a sloped inner sidewall. The fourth silicide layer 295D is contiguous and conformal with the two separate horizontal frontside surfaces, the vertical inner sidewall, and a portion of the sloped inner sidewall. The fourth silicide layer 295D has substantially a stair-shaped profile through a cross section of a source/drain region 104 (FIG. 1).

The second lower source/drain contact 290 (i.e., the lower source/drain contact in the claims) extends upwards from a frontside of the first nanodevice ND1 to connect to the fourth silicide layer 295D. The fifth silicide layer 295E (i.e., the additional silicide layer in the claims) connects to a frontside surface of the third upper source/drain 235C (i.e., the second upper source/drain in the claims). The third frontside source/drain contact 275C (i.e., the frontside source/drain contact in the claim) connects to a frontside surface of the fifth silicide layer 295E.

A frontside surface of the fourth silicide layer 295D extends a first width W1 along a y-axis. A backside surface of the second lower source/drain contact 290 extends a second width W2 along the y-axis. The first width W1 is greater than the second width W2.

The upper source/drain contact 315C, 319 extends downwards from a backside surface of the first nanodevice ND1 to connect to the second upper source/drain 235B. The upper source/drain contact 315C, 319 includes a head section 315C and a shaft section 319. The shaft section 319 extends from where the head section 315C connects to the shaft section 319 to the backside surface of the second upper source/drain 235B. A backside surface of the head section 315C extends a third width W3 along the y-axis and a frontside surface of the shaft section 319 extends a fourth width W4 along the y-axis. The third width W3 is greater than the fourth width W4. The second backside source/drain contact 315B, 317 (i.e., the backside source/drain contact in the claims) connects to a backside surface of the third lower source/drain 150C.

The first dielectric liner (i.e., the dielectric liner in the claims) of the plurality of dielectric liners 195 is in direct contact with a vertical outer sidewall of the second lower source/drain 150B. The first dielectric liner of the plurality of dielectric liners 195 is located between the second lower source/drain 150B and the shaft section 319 of the upper source/drain contact 315C, 319.

It may be appreciated that FIGS. 1-54 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first nanodevice including a plurality of first upper transistors and a plurality of first lower transistors, wherein the first nanodevice includes a first upper source/drain and a first lower source/drain that are offset from each other across the plurality of first upper transistors and the plurality of first lower transistors, wherein the first upper source/drain includes a frontside surface and a backside surface and the first lower source/drain includes two separate horizontal frontside surfaces and a vertical inner sidewall, wherein the vertical inner sidewall is located between the two separate horizontal frontside surfaces; and
a silicide layer contiguous and conformal with the two separate horizontal frontside surfaces and the vertical inner sidewall.

2. The semiconductor device of claim 1, wherein the first lower source/drain further includes a sloped inner sidewall, wherein the silicide layer is contiguous and conformal with the two separate horizontal frontside surfaces, the vertical inner sidewall, and a portion of the sloped inner sidewall.

3. The semiconductor device of claim 1, wherein the silicide layer has substantially a stair-shaped profile through a cross section of a source/drain region.

4. The semiconductor device of claim 1, further comprising:
a lower source/drain contact extending upwards from a frontside of the first nanodevice to connect to the silicide layer.

5. The semiconductor device of claim 4, wherein a frontside surface of the silicide layer extends a first width along a y-axis, wherein a backside surface of the lower source/drain contact extends a second width along the y-axis, and wherein the first width is greater than the second width.

6. The semiconductor device of claim 5, further comprising:
an upper source/drain contact extending downwards from a backside surface of the first nanodevice to connect to the first upper source/drain, wherein the upper source/drain contact includes a head section and a shaft section, wherein the shaft section extends from where the head section connects to the shaft section to the backside surface of the first upper source/drain, wherein a backside surface of the head section extends a third width along the y-axis and a frontside surface of the shaft section extends a fourth width along the y-axis, and wherein the third width is greater than the fourth width.

7. The semiconductor device of claim 6, further comprising:
a dielectric liner in direct contact with a vertical outer sidewall of the first lower source/drain, wherein the dielectric liner is located between the first lower source/drain and the shaft section of the upper source/drain contact.

8. A semiconductor device comprising:
a first nanodevice including a plurality of first upper transistors and a plurality of first lower transistors, wherein the first nanodevice includes a first upper source/drain and a first lower source/drain that are offset from each other across the plurality of first upper transistors and the plurality of first lower transistors, wherein the first upper source/drain includes a frontside surface and a backside surface and the first lower source/drain includes two separate horizontal frontside surfaces and a vertical inner sidewall, wherein the vertical inner sidewall is located between the two separate horizontal frontside surfaces;
a second nanodevice including a plurality of second upper transistors and a plurality of second lower transistors, wherein the second nanodevice is located adjacent to and parallel to the first nanodevice along an x-axis, wherein the second nanodevice includes a second upper source/drain and a second lower source/drain that are offset from each other across the plurality of second upper transistors and the plurality of second lower transistors; and
a silicide layer contiguous and conformal with the two separate horizontal frontside surfaces and the vertical inner sidewall.

9. The semiconductor device of claim 8, wherein the first lower source/drain further includes a sloped inner sidewall, wherein the silicide layer is contiguous and conformal with the two separate horizontal frontside surfaces, the vertical inner sidewall, and a portion of the sloped inner sidewall.

10. The semiconductor device of claim 8, wherein the silicide layer has substantially a stair-shaped profile through a cross section of a source/drain region.

11. The semiconductor device of claim 8, further comprising:
a lower source/drain contact extending upwards from a frontside of the first nanodevice to connect to the silicide layer;
an additional silicide layer connected to a frontside surface of the second upper source/drain; and
a frontside source/drain contact connected to a frontside surface of the additional silicide layer.

12. The semiconductor device of claim 11, wherein a frontside surface of the silicide layer extends a first width along a y-axis, wherein a backside surface of the lower source/drain contact extends a second width along the y-axis, and wherein the first width is greater than the second width.

13. The semiconductor device of claim 12, further comprising:
an upper source/drain contact extending downwards from a backside surface of the first nanodevice to connect to the first upper source/drain, wherein the upper source/drain contact includes a head section and a shaft section, wherein the shaft section extends from where the head section connects to the shaft section to the backside surface of the first upper source/drain, wherein a backside surface of the head section extends a third width along the y-axis and a frontside surface of the shaft section extends a fourth width along the y-axis, and wherein the third width is greater than the fourth width.

14. The semiconductor device of claim 13, further comprising:
a dielectric liner in direct contact with a vertical outer sidewall of the first lower source/drain, wherein the dielectric liner is located between the first lower source/drain and the shaft section of the upper source/drain contact.

15. A semiconductor device comprising:
a first nanodevice including a plurality of first upper transistors and a plurality of first lower transistors, wherein the first nanodevice includes a first upper source/drain and a first lower source/drain that are offset from each other across the plurality of first upper transistors and the plurality of first lower transistors, wherein the first upper source/drain includes a frontside surface and a backside surface and the first lower source/drain includes two separate horizontal frontside surfaces and a vertical inner sidewall, wherein the vertical inner sidewall is located between the two separate horizontal frontside surfaces;
a second nanodevice including a plurality of second upper transistors and a plurality of second lower transistors, wherein the second nanodevice is located adjacent to and parallel to the first nanodevice along an x-axis, wherein the second nanodevice includes a second upper source/drain and a second lower source/drain that are offset from each other across the plurality of second upper transistors and the plurality of second lower transistors;
a silicide layer contiguous and conformal with the two separate horizontal frontside surfaces and the vertical inner sidewall; and
a backside source/drain contact connected to a backside surface of the second lower source/drain.

16. The semiconductor device of claim 15, wherein the first lower source/drain further includes a sloped inner sidewall, wherein the silicide layer is contiguous and conformal with the two separate horizontal frontside surfaces, the vertical inner sidewall, and a portion of the sloped inner sidewall.

17. The semiconductor device of claim 15, wherein the silicide layer has substantially a stair-shaped profile through a cross section of a source/drain region.

18. The semiconductor device of claim 15, further comprising:
a lower source/drain contact extending upwards from a frontside of the first nanodevice to connect to the silicide layer;
an additional silicide layer connected to a frontside surface of the second upper source/drain; and
a frontside source/drain contact connected to a frontside surface of the additional silicide layer.

19. The semiconductor device of claim 18, wherein a frontside surface of the silicide layer extends a first width along a y-axis, wherein a backside surface of the lower source/drain contact extends a second width along the y-axis, and wherein the first width is greater than the second width.

20. The semiconductor device of claim 19, further comprising:
an upper source/drain contact extending downwards from a backside surface of the first nanodevice to connect to the first upper source/drain, wherein the upper source/drain contact includes a head section and a shaft section, wherein the shaft section extends from where the head section connects to the shaft section to the backside surface of the first upper source/drain, wherein a backside surface of the head section extends a third width along the y-axis and a frontside surface of the shaft section extends a fourth width along the y-axis, and wherein the third width is greater than the fourth width.
